(19) United States
(12) Patent Application Publication
(10) Pub. No.: US 2009/0291523 A1
(43) Pub. Date: Nov. 26, 2009

(54) Method of Manufacturing High Quality ZnO Monocrystal Film on Silicon(111) Substrate

(75) Inventors: Xiaolong Du, Beijing (CN); Xina Wang, Beijing (CN); Zhaoquan Zeng, Beijing (CN); Hongtao Yuan, Beijing (CN); Zengxia Mei, Beijing (CN); Qikun Xue, Beijing (CN); Jinfeng Jia, Beijing (CN)

Correspondence Address: AKC PATENTS, 215 GROVE ST., NEWTON, MA, 02466, US

(73) Assignee: THE INSTITUTE OF PHYSICS, CHINESE ACADEMY OF SCIENCE, Beijing (CN)

(21) Appl. No.: 12/293,448

(22) PCT Filed: Apr. 11, 2006
(86) PCT No.: PCT/CN06/00644

§ 371 Date: Sep. 18, 2008

(30) Foreign Application Priority Data
Mar. 20, 2006 (CN) 200610064977.5

(51) Int. Cl. H01L 21/20

(52) U.S. Cl. 438/104; 257/E21.09

(57) ABSTRACT

There is provided a method of manufacturing high quality ZnO manufacturing film on silicon (111) substrate, including the following steps: removing silicon oxide on the surface of silicon (111) substrate; depositing metal monocrystal film having 1-10 nm thickness, such as Mg, Ca, Sr, Cd etc, at low temperature; oxiding the metal film at low temperature to obstain metal oxide monocrystal layer; depositing ZnO buffer layer at low temperature; depositing ZnO epitaxial layer at high temperature. The ZnO film is suitable for fabrication of high performance of photoelectron device.

### FIELD OF THE INVENTION

The present invention relates to a method of manufacturing a wide-bandgap semiconductor zinc oxide (ZnO) monocrystal film.

### BACKGROUND OF THE INVENTION

As a core basic material of the third generation semiconductor, ZnO has excellent photoelectronic performance, with the bandgap width at room temperature being 3.37 eV and the free exciton binding energy 60 meV. It has become another important wide bandgap semiconductor material after GaN (with the free exciton binding energy of 25 meV), and has a wide application prospect in manufacturing high-performance short-wavelength photoelectronic devices. Its application in devices is based on manufacturing a device quality ZnO-based epitaxial film. Although a ZnO monocrystal substrate has been commercialized, it is still too expensive. Therefore, the homoepitaxial growth technology of the ZnO monocrystal film cannot currently be applied to industry. Similar to the case of GaN, sapphire is a common substrate for the epitaxial growth of ZnO-based film. However, the insulated sapphire substrate makes it more difficult to prepare a p-n junction ZnO-based device. This difficulty in manufacturing the ZnO-based device can be solved with a Si substrate. Moreover, the Si substrate is inexpensive and has high crystalline quality, and its unique electric conductivity makes the follow-up device preparation processes easier. It is possible to make the ZnO-based device with the Si substrate into a monolithic integrated circuit, which will allow an effective combination with the advanced Si-based microelectronic technology. Therefore, it has a significant meaning for manufacturing the high-quality ZnO epitaxial film on the Si substrate. Because of this, the Si-based ZnO film preparation technology is attracting more concerns in recent years.

However, there are currently few reports in the world about epitaxial growth of the ZnO film, especially the high-quality ZnO monocrystal film, on the Si substrate. One of the important reasons is that Si is easy to form amorphous-structured silicon oxide (SiOₓ) in an oxygen environment, which thus makes the ZnO epitaxial growth very difficult At present, some surface and interface treatment technologies have been developed at domestically and abroad to protect the silicon surface, and thus the ZnO film has been prepared. For instance, a Japanese patent JP2003165793 adopted a method of predepositing a monocrystal CaF₂ layer on the Si substrate to protect the silicon surface, so as to prepare the ZnO monocrystal film. The Zhuxi Fu team of the University of Science and Technology of China pre-prepared a SiC layer on the Si substrate, and then grew the ZnO film, which achieved certain effects (Chinese Journal of Semiconductors, V25, 1662 (2004)). The Kawasaki team of the Tohoku University (Japan) prepared the ZnO film by using a ZnS layer as a buffer layer, and the room-temperature photoluminescence spectrum indicated that the epitaxial film possessed strong yellow-green deep level luminescence, which indicated that the film had a high defect density (Appl. Phys. Lett. V84, 502 (2004), V85, 5586 (2004)). Moreover, Fujita et al. in the Waseda University (Japan) deposited Mg for 2 minutes at 350° C. before introducing oxygen gas to prepare an MgO buffer layer of 20 nm, thus obtaining the ZnO film (J. Vax. Sci. Technol. B V 22, 1484 (2004)). It is well known that, Si will react with the active metal of magnesium at high temperature to form magnesium silicide, and a layer of magnesium silicide (MgₓSi) on the surface of Si may influence the growth of MgO, thus influencing quality of the ZnO epitaxial layer.

Therefore, the key for manufacturing the high-quality Si-based ZnO monocrystal film is to develop an interface engineering technology that can effectively prevent the surface of Si (111) from being oxidized, and establish a suitable template for the ZnO epitaxial growth.

### DISCLOSURE OF THE INVENTION

A purpose of the present invention is to provide a new method of manufacturing the high-quality ZnO monocrystal film on the surface of Si (111). The method includes the following five sequential steps, heat treating the Si substrate under an ultrahigh vacuum environment to obtain the clean surface of Si (111), depositing a monocrystal film of 1-10 nm of such metals as magnesium, calcium, strontium or cadmium at low temperature, oxidizing the metal film at low temperature to obtain a halite-phase metal-oxide monocrystal layer, depositing a ZnO buffer layer at low temperature, and depositing the ZnO layer at high temperature. The high-quality ZnO monocrystal film is thus obtained, whose excellent photoelectronic performance indicates that this film is highly suitable for manufacturing the high-performance photoelectronic devices.

The method of manufacturing the high-quality ZnO monocrystal film on the Si (111) surface according to the invention can be executed according to the following technical solution:
1) Remove the oxide layer on the surface of Si (111) substrate by means of the publicly-known hydrofluoric-acid corrosion method, and then introduce the substrate into an ultrahigh-vacuum film preparation system, whose specimen stage has heating and cooling functions;
2) remove the remaining silicon oxide layer at the high temperature of 750° C.˜950° C. under a UHV (ultrahigh vacuum) environment to obtain the clean surface of Si substrate;
3) cool the above-mentioned Si substrate to 100° C.˜−150° C., deposit the metal monocrystal film of 1˜10 nm of magnesium, calcium, strontium or cadmium, and then oxidize the metal film with oxygen gas or an active oxygen source to obtain the halite-phase metal-oxide monocrystal film;
4) deposit the ZnO film on the above-mentioned metal-oxide layer by means of the publicly-known two-step growth method, that is, deposit the ZnO buffer layer of 5˜50 nm at the low temperature of −150° C.˜350° C.; and
5) deposit the ZnO epitaxial layer of 300˜1000 nm at 400° C.˜700° C. to obtain the high-quality ZnO film.

Further, the ultrahigh vacuum film-preparation system is a molecular beam epitaxy (MBE) system.

Further, the magnesium-oxide monocrystal film is prepared in Step 3) by cooling the Si substrate to 30° C.˜−30° C., depositing the Mg monocrystal layer of 1˜10 nm, and then oxidizing the Mg film with the active oxygen source for 10˜30 minutes; and then in Step 4) the ZnO buffer layer of 5˜50 nm is deposited on the magnesium oxide layer at the low temperature of −30° C.˜350° C.

The difference between the above-mentioned method of manufacturing the ZnO monocrystal film and the prior art method lies mainly in that depositing the monocrystal film of metal Mg at low temperature to protect the clean Si (111) surface, and obtaining the magnesium oxide monocrystal film by means of the active oxygen treatment at low temperature. Being at low temperature aims to prevent a silicification reaction between Si and Mg through mutual diffusion, which may influence the interface between Si and Mg; moreover, depositing Mg at low temperature may decrease the desorption speed of Mg, so as to obtain a stable monocrystal layer. We found the obvious mutual diffusion between Si and Mg above 60° C., whereby an Mg₂Si layer is formed as a result. We clearly observed the related patterns of Mg₂Si (111) with RHEED (Reflection High Energy Electron Diffraction), which indicates that there is Mg₂Si formed on Si. However, there is apparently less mutual diffusion through the interface below 30° C., which may allow to obtain the high crystalline Mg monocrystal film, which has been proved by the clear RHEED patterns of Mg (0001). After the low-temperature Mg monocrystal film is formed, an active oxygen source is introduced, such as oxygen-contained RF plasma, ECR (Electron Cyclotron Resonance) plasma or ozone. The active oxygen diffuses toward the Mg film, thus gradually oxidizing the Mg film into the monocrystal magnesium oxide. Since the formation enthalpy Hf (MgO) of MgO is much smaller than the formation enthalpy Hf (SiO₂) of SiO₂, it is difficult for Si to combine with oxygen, which thus protects the surface of Si. The RHEED patterns indicate that the high-quality halite-phase MgO monocrystal layer can be obtained by this method, which thus provides a good template for the epitaxial growth of ZnO. We obtained the high-quality ZnO monocrystal film by the two-step method.

Further, the calcium-oxide monocrystal film is prepared in Step 3) by cooling the Si substrate to −10° C.˜−100° C., depositing the metal Ca monocrystal layer of 1˜5 nm, and then oxidizing the metal Ca film with the active oxygen source for 10˜30 minutes; and then in Step 4) the ZnO buffer layer of 5˜50 nm is deposited on the calcium oxide layer at the low temperature of −100° C.˜350° C.

The above-mentioned method of manufacturing the ZnO monocrystal film by protecting the surface of Si substrate through depositing Ca at low temperature is different from that through depositing Mg at low temperature mainly in that, the deposition temperature and the oxidation temperature of metal Ca are lower than those of Mg. This is because Ca is more active than Mg, and thus easier to react with Si to produce calcium silicide (CaSiₓ). We discovered in our research that, we could not obtain the metal Ca monocrystal film when the temperature is above 0° C. because of the reaction between Si and Ca. Therefore, lower temperature is needed for the deposition of Ca. Similarly, the oxidization temperature of Ca is lower, too. Ca has a cubic close-packed structure with a lattice constant of 0.559 nm, the lattice mismatch between Ca and Si (a=0.543 nm) is only 2.8%, and thus it is easy to prepare a high-quality film. Moreover, the halite-phase calcium oxide has a lattice constant of 0.481 nm, the lattice in its (111) face is just between Si (111) and ZnO (0001) and closer to ZnO (the lattice mismatch is 4.5%), which is very suitable for the growth of ZnO.

Further, the strontium-oxide monocrystal film is prepared in Step 3) by cooling the Si substrate to −50° C.˜−150° C., depositing the metal Sr monocrystal film of 1˜5 nm, and then oxidizing the metal Sr film for 10˜30 minutes by introducing oxygen gas or active oxygen; and then in Step 4) the ZnO buffer layer of 5˜50 nm is deposited on the strontium oxide layer at the low temperature of −150° C.˜350° C.

Sr is more active, thus the above-mentioned deposition temperature of Sr is lower than that of Ca and Mg, and oxygen gas can be used instead of active oxygen to oxidize metal Sr, which is more convenient for operation. Sr has a cubic close-packed structure with a lattice constant of 0.608 nm, the lattice mismatch between Sr and Si (a=0.543 nm) is 12%, and thus a high-quality Sr film can be obtained. Moreover, the halite-phase strontium oxide has a lattice constant of 0.516 nm, the lattice in its (111) face is between Si (111) and ZnO (0001), which is also suitable for the growth of ZnO.

Further, the cadmium-oxide monocrystal film is prepared in Step 3) by cooling the Si substrate to 100° C.˜−20° C., depositing the metal Cd monocrystal layer of 2˜10 nm, and then oxidizing the metal Cd film with the active oxygen source for 10˜30 minutes; and then in Step 4) the ZnO buffer layer of 5˜50 nm is deposited on the cadmium oxide layer at the low temperature of −20° C.˜350° C.

Cd is the least active among the four metal elements, therefore the above-mentioned deposition temperature of Cd is also the highest, and meanwhile active oxygen is needed to oxidize metal Cd. Being similar to Mg, Cd has a hexagonal close-packed crystal structure, with a lattice constant of 0.298 nm. Therefore, there is a domain-matching growth mode of 4:3 for the face of Cd (0001) and the face of Si (111), that is, 4 lattices of Cd match with 3 lattices of Si, with the lattice mismatch being only 3%. Therefore, the high-quality Cd film can be obtained. Moreover, the halite-phase cadmium oxide has a lattice constant of 0.471 nm, the lattice in its (111) face is between Si (111) and ZnO (0001) and closer to ZnO (the lattice mismatch is 2.5%), which is very suitable for the growth of ZnO.

### BRIEF DESCRIPTION OF THE DRAWINGS

FIG. 1 is a process flow chart of manufacturing the high-quality ZnO monocrystal film on Si (111) according to the invention.

FIG. 2 shows the in-situ observed RHEED patterns of the ZnO monocrystal film prepared in Embodiment 1 of the invention.

FIG. 3 shows an AFM (Atom Force Microscope) photograph of the ZnO monocrystal film prepared in Embodiment 1 of the invention.

FIG. 4 shows a θ-2θ scan X-ray diffraction pattern and a ω-scan rocking curve of the ZnO monocrystal film prepared on Si (111) in Embodiment 1 of the invention.

FIG. 5 is a room-temperature photoluminescence spectrum of the ZnO sample prepared in Embodiment 1 of the invention.

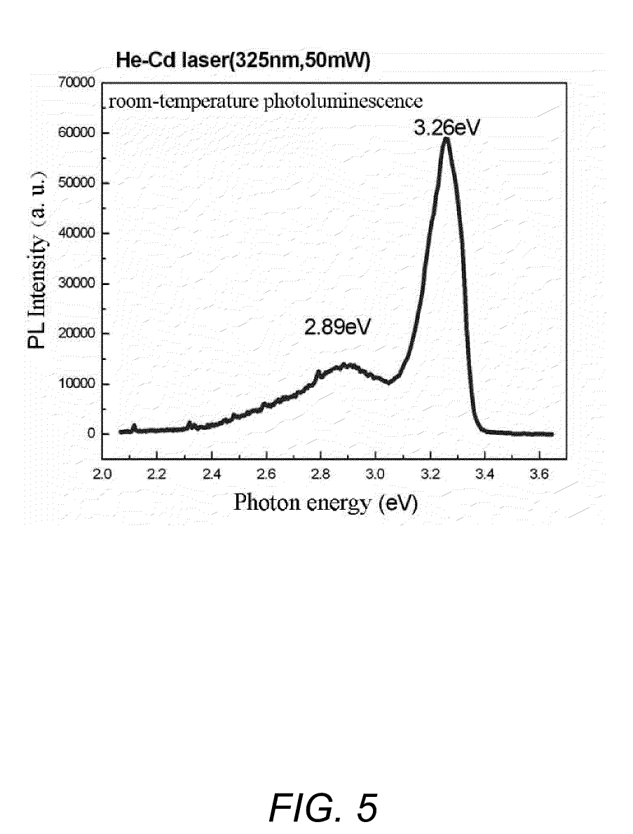

FIG. 6 shows the RHEED patterns of the Mg film and the halite-phase magnesium oxide film prepared at 30° C. in Embodiment 2 of the invention.

FIG. 7 shows the RHEED patterns of the Mg film and the halite-phase magnesium oxide film prepared at −30° C. in Embodiment 3 of the invention.

### DETAILED DESCRIPTION OF THE INVENTION

The invention will be explained in detail below with reference to the accompanying drawings according to the manufacturing method of the present invention.

### Embodiment 1

### Preparation of the High-Quality ZnO Thin Film by Predepositing the Metal Mg Monocrystal Thin Layer on Si (111)

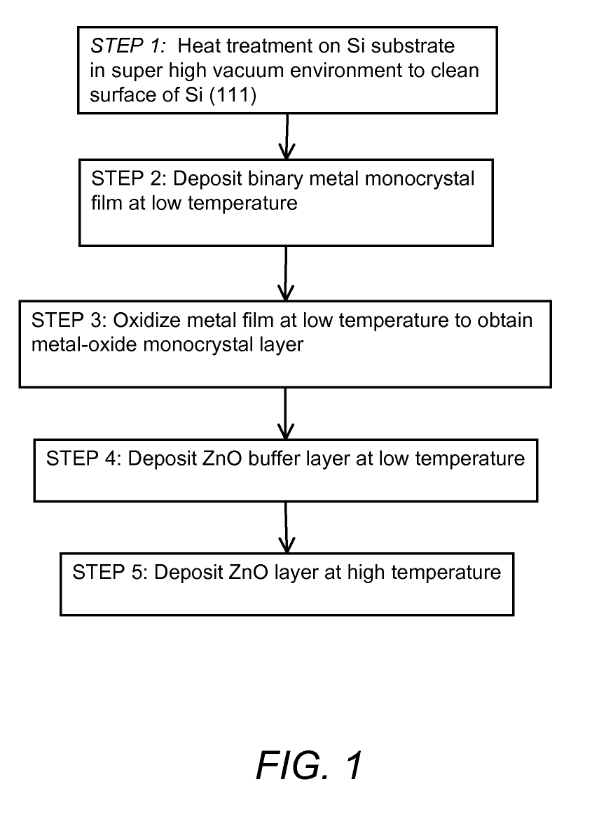

In the process flow chart of the invention as shown in FIG. 1, the high-quality ZnO thin film can be prepared by predepositing the metal Mg monocrystal thin layer on the substrate of Si (111), with the specific steps as follows:
1. Remove the silicon oxide layer on the surface of commercially available Si (111) substrate by means of the publicly-known hydrofluoric acid corrosion method, and introduce the substrate into the MBE system;
2. raise the temperature to 900° C. at atmospheric pressure below 5.0×10⁻⁷ Pa and keep for 20 minutes, so as to remove the remaining silicon oxide layer on the surface of Si by high-temperature desorption, and obtain the clean surface of Si substrate;
3. cool the Si substrate to −10° C., and here its surface shows typical (7×7) reconstruction; heat an Mg diffusion furnace to make the Mg beam reach 8×10⁻⁵ Pa; and deposit the metal Mg monocrystal layer of 5 nm;
4. open the oxygen radio frequency plasma source to oxidize the metal Mg film for 15 minutes, thus obtaining the magnesium oxide monocrystal layer; wherein the flow of oxygen gas is 1 SCCM, and the power of ratio frequency 200 watt; and
5. deposit the ZnO film on the above-mentioned magnesium oxide layer by means of the publicly-known two-step growth method, that is, deposit the ZnO buffer layer of 20 nm at low temperature (100° C.) and the ZnO epitaxial layer of 800 nm at higher temperature (600° C.), thus obtaining the high-quality ZnO film.

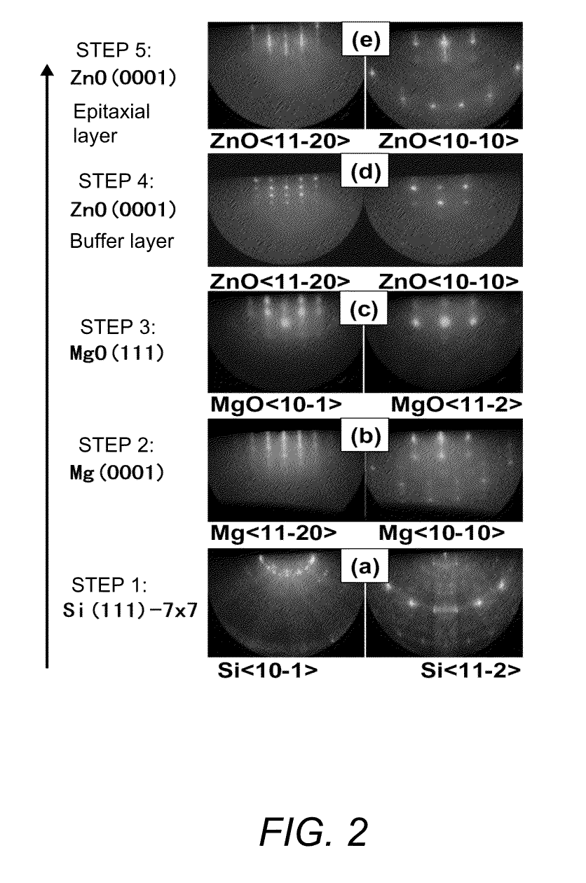

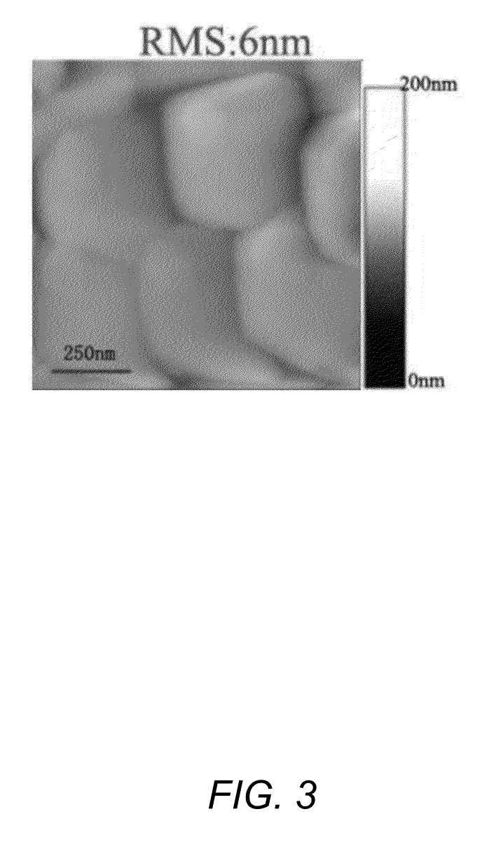

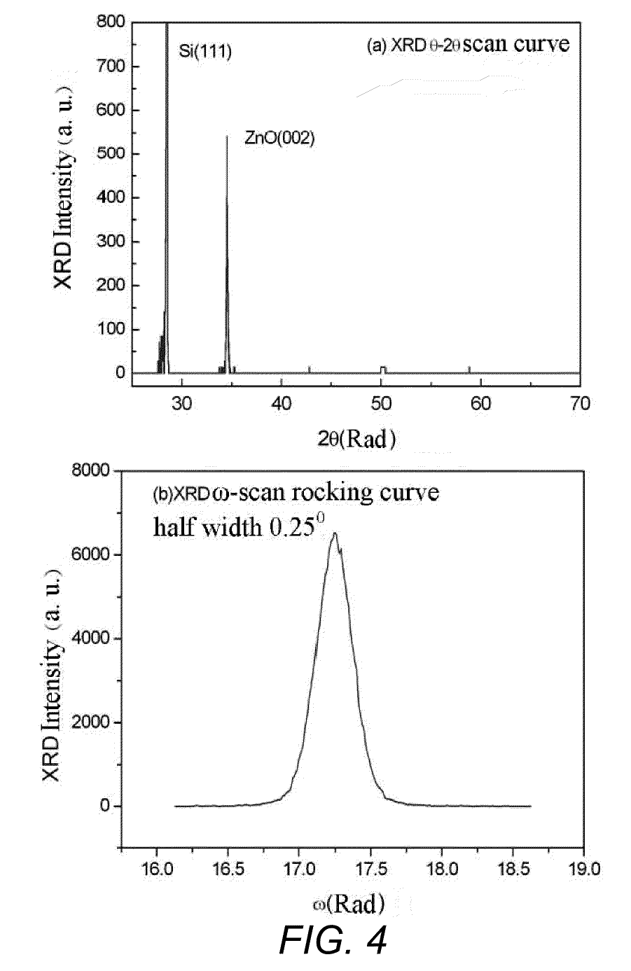

We made an in-situ Reflection High Energy electron Diffraction (RHEED) observation on the samples during the above-mentioned preparation process, with the samples corresponding to the 5 steps of the film-preparation process. The results are shown in FIG. 2. FIG. 2 (a) is the clean surface of Si (111) substrate after a high-temperature treatment under ultrahigh vacuum, the surface here showing clear (7×7) reconstruction. FIG. 2 (b) is the RHEED pattern of the metal Mg layer deposited on Si (111), which shows a sharp linear diffraction pattern, indicating that Mg (0001) has good crystallizability, and the low-temperature deposition of Mg can sufficiently reduce the mutual diffusion between Si and Mg and prevent the reaction between them; the pattern also indicates that the lattice in Mg (0001) overlaps the lattice of Si (111), and here Mg <10-10>//<Si<11-2> and Mg <11-20>//Si<10-1>. FIG. 2 (c) is the surface of metal Mg after being oxidized; this pattern shows the typical halite-phase magnesium oxide, whose growth face is the (111) face, the lattice in which overlaps the lattice of Si (111), i.e. MgO<11-2>//Si<11-2> and Mg<10-1>//Si<10-1>. FIG. 2 (d) is the surface after the ZnO buffer layer is grown; the film is of a typical three-dimensional island growth mode at low temperature, which is very advantageous to sufficiently relax a strain caused by a large lattice mismatch. FIG. 2 (e) is the surface after the ZnO epitaxial layer is grown, and the pattern indicates that the film obtained is the high-quality ZnO monocrystal film. We observed the surface topography of this film by the AFM, and the result is as shown in FIG. 3, which shows the typical grain-type topography, the surface roughness being 6 nm within a range of 1×1 μm². We also conducted an X-ray diffraction test on the sample, and the result is shown in FIG. 4. FIG. 4 (a) is the θ-2θ scan curve, which shows a peak of Si and a peak of ZnO (002), indicating that ZnO grows along the axis of c. FIG. 4 (b) is the co-scan rocking curve of ZnO (002), whose half width is only 0.25⁰, indicating good crystallizability, the film being one of the best Si-based ZnO films at present. The room-temperature photoluminescence test indicates that this film has a very strong bandside light-emitting peak (located at 3.26 eV), a weak blue-emission peak (located at 2.89 eV), and a hardly detected yellow-green emission peak, which indicate that the film has good optical performance and is very suitable for manufacturing the high-performance photoelectronic devices.

### Embodiment 2

### Preparation of the High-Quality ZnO Thin Film by Predepositing the Metal Mg Monocrystal Thin Layer on Si (111)

In the process flow chart of the invention as shown in FIG. 1, the high-quality ZnO thin film can be prepared by predepositing the metal Mg monocrystal thin layer on the substrate of Si (111), with the specific steps as follows:
1. Remove the silicon oxide layer on the surface of commercially available Si (111) substrate by means of the publicly-known hydrofluoric acid corrosion method, and introduce the substrate into the MBE system;
2. raise the temperature to 900° C. at atmospheric pressure below 5.0×10⁻⁷ Pa and keep for 20 minutes, so as to remove the remaining silicon oxide layer on the surface of Si by high-temperature desorption, and obtain the clean surface of Si substrate;
3. cool the Si substrate to 30° C., and here its surface shows typical (7×7) reconstruction; heat the Mg diffusion furnace to make the Mg beam reach 8×10⁻⁵ Pa, and deposit the metal Mg monocrystal layer of 10 nm;
4. open the oxygen radio frequency plasma source to oxidize the metal Mg film for 30 minutes, thus obtaining the magnesium oxide monocrystal layer; wherein the flow of oxygen gas is 1 SCCM, and the power of ratio frequency 200 watt; and
5. deposit the ZnO film on the above-mentioned magnesium oxide layer by means of the publicly-known two-step growth method, that is, deposit the ZnO buffer layer of 20 nm at low temperature (100° C.) and the ZnO epitaxial layer of 800 nm at higher temperature (600° C.), thus obtaining the high-quality ZnO film.

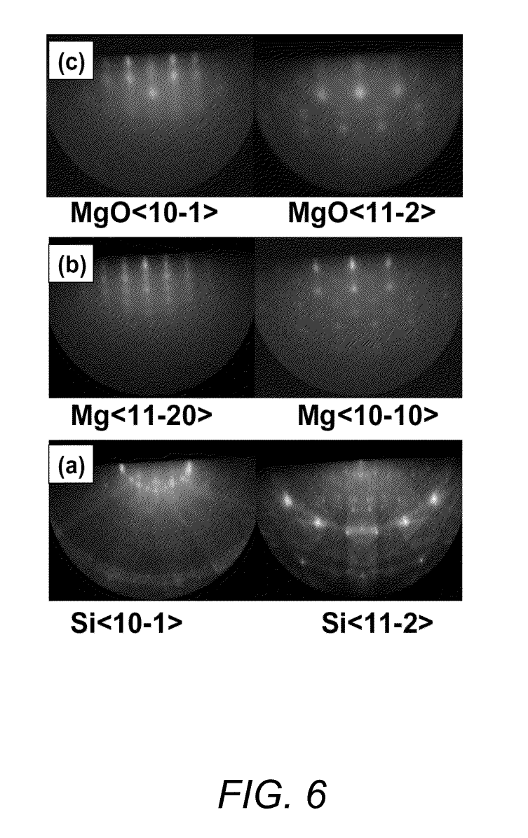

Compared with the sample preparation in Embodiment 1, this embodiment uses higher temperature (30° C.) for depositing the metal Mg, and deposits a thicker Mg film (10 nm); in order to oxidize the Mg film, we prolonged the oxidization time (30 minutes), and obtained a very good halite-phase magnesium oxide template as well. FIG. 6 is the RHEED patterns of Mg film and magnesium oxide film observed during preparation of this sample. FIG. 6 (a) is the surface of Si (111)-7×7;and FIG. 6 (b) indicates that the Mg film is a monocrystal film, whose growth face is Mg (0001). The Mg film is of poorer quality compared with Embodiment 1, because the mutual diffusion between Mg and Si is not suppressed completely at 30° C., and the interface between Si and Mg is not very steep, which thus influences the quality of magnesium oxide as shown in FIG. 6 (c). The halite-phase magnesium oxide is of poorer crystallizability than the sample of Embodiment 1. The ZnO monocrystal film is finally prepared, however with somewhat poorer quality. This embodiment indicates that the deposition of Mg film is the key for manufacturing the high-quality ZnO film, and the deposition temperature of the Mg film cannot be too high.

### Embodiment 3

### Preparation of the High-Quality ZnO Thin Film by Predepositing the Metal Mg Monocrystal Thin Layer on Si (111)

In the process flow chart of the invention as shown in FIG. 1, the high-quality ZnO thin film can be prepared by predepositing the metal Mg monocrystal thin layer on the substrate of Si (111), with the specific steps as follows:
1. Remove the silicon oxide layer on the surface of commercially available Si (111) substrate by means of the publicly-known hydrofluoric acid corrosion method, and introduce the substrate into the MBE system;
2. raise the temperature to 900° C. at atmospheric pressure below 5.0×10⁻⁷ Pa and keep for 20 minutes, so as to remove the remaining silicon oxide layer on the surface of Si by high-temperature desorption, and obtain the clean surface of Si substrate;
3. cool the Si substrate to −30° C., and here its surface shows typical (7×7) reconstruction; heat the Mg diffusion furnace to make the Mg beam reach 8×10⁻⁵ Pa; and deposit the metal Mg monocrystal layer of 2 nm;
4. open the oxygen radio frequency plasma source to oxidize the metal Mg film for 10 minutes, thus obtaining the magnesium oxide monocrystal layer; wherein the flow of oxygen gas is 1 SCCM, and the power of ratio frequency 200 watt; and
5. deposit the ZnO film on the above-mentioned magnesium oxide layer by means of the publicly-known two-step growth method, that is, deposit the ZnO buffer layer of 20 nm at low temperature (100° C.) and the ZnO epitaxial layer of 800 nm at higher temperature (600° C.), thus obtaining the high-quality ZnO film.

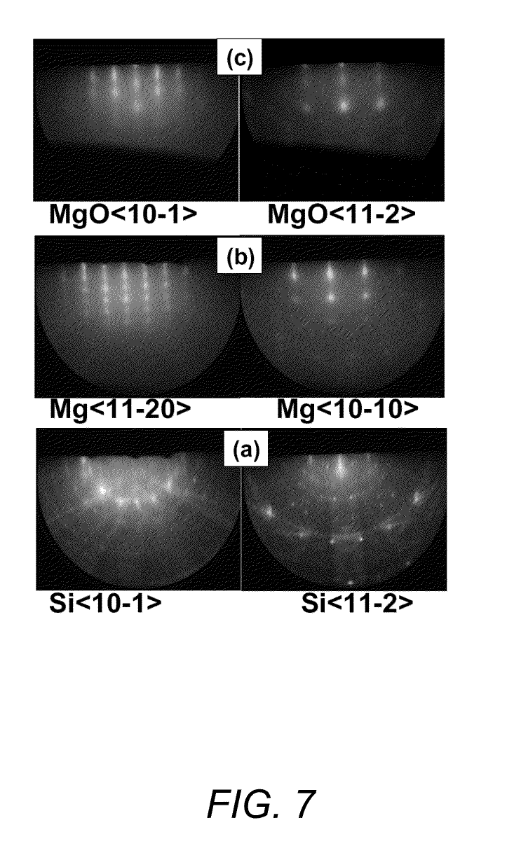

Compared with the sample preparations in Embodiments 1 and 2, this Embodiment uses lower temperature (−30° C.) for depositing metal Mg of 2 nm, and obtains a better halite-phase magnesium oxide template during a shorter oxidization time, with the result closer to that of Embodiment 1. FIG. 7 is the RHEED patterns of Mg film and magnesium oxide film observed during preparation of this sample. FIG. 7 (a) is the surface of Si (111)-7×7; FIG. 7 (b) indicates that the Mg film is a monocrystal film, whose growth face is Mg (0001); and FIG. 7 (c) indicates that the magnesium oxide film is a halite-phase monocrystal film, whose growth face is MgO (111).

By comparing Embodiments 1, 2 and 3,we found that the metal Mg monocrystal film can be obtained on the clean surface of Si below 30° C.; the interface between Si and Mg is sharper when the temperature is lower, which can better protect the surface of Si and obtain a high-quality magnesium oxide template. The mutual diffusion between Mg and Si is nearly suppressed below −10° C., and therefore a similar result can be obtained. We conducted the XRD test on the above-mentioned samples, and found that the ZnO films obtained in Embodiments 1 and 3 are basically of the same quality, while the one obtained in Embodiment 2 is somewhat poorer.

### Embodiment 4

### Preparation of the High-Quality ZnO Thin Film by Predepositing the Metal Ca Monocrystal Thin Layer on Si (111)

In the process flow chart of the invention as shown in FIG. 1, the high-quality ZnO thin film can be prepared by predepositing the metal Ca monocrystal thin layer on the substrate of Si (111), with the specific steps as follows:
1. Remove the silicon oxide layer on the surface of commercially available Si (111) substrate by means of the publicly-known hydrofluoric acid corrosion method, and introduce the substrate into the MBE system;
2. raise the temperature to 900° C. at atmospheric pressure below 5.0×10⁻⁷ Pa and keep for 20 minutes, so as to remove the remaining silicon oxide layer on the surface of Si by high temperature desorption, and obtain the clean surface of Si substrate;
3. cool the Si substrate to −50° C., and here its surface shows typical (7×7) reconstruction; heat a Ca diffusion furnace to make the Ca beam reach 5×10⁻⁵ Pa; and deposit the metal Ca monocrystal layer of 3 nm;
4. open the oxygen radio frequency plasma source to oxidize the metal Ca film for 15 minutes, thus obtaining the calcium oxide monocrystal layer; wherein the flow of oxygen gas is 1 SCCM, and the power of ratio frequency 200 watt; and
5. deposit the ZnO film on the above-mentioned calcium oxide layer by means of the publicly-known two-step growth method, that is, deposit the ZnO buffer layer of 20 nm at low temperature (100° C.) and the ZnO epitaxial layer of 800 nm at higher temperature (600° C.), thus obtaining the high-quality ZnO film.

Compared with the method of manufacturing the ZnO sample by depositing Mg in Embodiments 1, 2 and 3,only by depositing metal Ca at lower temperature can this method prevent the reaction between Si and Ca, and therefore there is a longer temperature-ramp process. It is found that the deposition temperature of Ca of above −10° C. is disadvantageous for depositing the monocrystal Ca film. In the solution of preparing ZnO with the Ca film, the deposition temperature of Ca is selected to be in the range of −10° C.˜100° C. The in-plane lattice constant of CaO (111) is between Si (111) and ZnO (0001), which is advantageous for reducing the lattice mismatch between Si and ZnO, thus a better film being obtained.

### Embodiment 5

### Preparation of the High-Quality ZnO Thin Film by Predepositing the Metal Sr Monocrystal Thin Layer on Si (111)

In the process flow chart of the invention as shown in FIG. 1, the high-quality ZnO thin film can be prepared by predepositing the metal Sr monocrystal thin layer on the substrate of Si (111), with the specific steps as follows:
1. Remove the silicon oxide layer on the surface of the commercially available Si (111) substrate by means of the publicly-known hydrofluoric acid corrosion method, and introduce the substrate into the MBE system;
2. raise the temperature to 900° C. at atmospheric pressure below 5.0×10⁻⁷ Pa and keep for 20 minutes, so as to remove the remaining silicon oxide layer on the surface of Si by high temperature desorption, and obtain the clean surface of Si substrate;
3. cool the Si substrate to −100° C., and here its surface shows typical (7×7) reconstruction; heat an Sr diffusion furnace to make the Sr beam reach 3×10⁻⁵ Pa; and deposit the metal Sr monocrystal layer of 3 nm;
4. open the oxygen gas source to oxidize the metal Sr film for 15 minutes, thus obtaining the strontium oxide monocrystal film; wherein the flow of oxygen gas is 2 SCCM; and
5. deposit the ZnO film on the above-mentioned strontium oxide layer by means of the publicly-known two-step growth method, that is, deposit the ZnO buffer layer of 20 nm at low temperature (0° C.) and the ZnO epitaxial layer of 800 nm at higher temperature (600° C.), thus obtaining the high-quality ZnO film.

Compared with the sample preparation in Embodiment 4, only by depositing metal Sr at lower temperature can this method prevent the reaction between Si and Sr, and therefore there is a longer temperature-ramp process. It is found that the deposition temperature of Sr of above −50° C. is disadvantageous for depositing the Sr monocrystal film. In the solution of manufacturing ZnO with the Sr film, the deposition temperature of Sr is selected to be in the range of −50° C.˜−150° C. Another feature of this method is that the method of introducing oxygen gas can be used to oxidize Sr, because Sr is very active and can react with oxygen gas directly and rapidly, without using the active oxygen source. Moreover, the in-plane lattice constant of SrO (111) is between Si (111) and ZnO (0001), which is advantageous for reducing the lattice mismatch between Si and ZnO, thus a high-quality film being obtained.

### Embodiment 6

### Preparation of the High-Quality ZnO Thin Film by Predepositing the Metal Cd Monocrystal Thin Layer on Si (111)

In the process flow chart of the invention as shown in FIG. 1, the high-quality ZnO thin film can be prepared by predepositing the metal Cd monocrystal thin layer on the substrate of Si (111), with the specific steps as follows:
1. Remove the silicon oxide layer on the surface of commercially available Si (111) substrate by means of the publicly-known hydrofluoric acid corrosion method, and introduce the substrate into the MBE system;
2. raise the temperature to 900° C. at atmospheric pressure below 5.0×10⁻⁷ Pa and keep for 20 minutes, so as to remove the remaining silicon oxide layer on the surface of Si by high-temperature desorption, and obtain the clean surface of Si substrate;
3. cool the Si substrate to 30° C., and here its surface shows typical (7×7) reconstruction; heat a Cd diffusion furnace to make the Cd beam reach 7×10⁻⁵ Pa; and deposit the metal Cd monocrystal layer of 7 nm;
4. open the oxygen radio frequency plasma source to oxidize the metal Cd film for 20 minutes, thus obtaining the cadmium oxide monocrystal film; wherein the flow of oxygen gas is 1 SCCM, and the power of ratio frequency 200 watt; and
5. deposit the ZnO film on the above-mentioned cadmium oxide layer by means of the publicly-known two-step growth method, that is, deposit the ZnO buffer layer of 20 nm at low temperature (100° C.) and ZnO epitaxial layer of 800 nm at higher temperature (600° C.), thus obtaining the high-quality ZnO film.

Compared with the methods of preparing the ZnO sample by depositing the metals Mg, Ca and Sr, this method can use the higher temperature to deposit metal Cd, because the reaction between Si and Cd is weak; the growth temperature of Cd is selected to be at −20° C. to 100° C., and therefore the temperature range is more narrow, which is convenient for execution. Moreover, Cd is weak to catch oxygen, and therefore the metal Cd film needs to be thicker to protect the surface of Si; the in-plane lattice constant of CdO (111) is between Si (111) and ZnO (0001), the lattice mismatch between CdO and ZnO is only 2.5%, and therefore CdO is very suitable for manufacturing the high-quality ZnO film.

1. A method of manufacturing a high-quality ZnO monocrystal film on a substrate of Si (111), comprising the following steps:
1) remove an oxide layer on the surface of Si (111) substrate by means of the publicly-known hydrofluoric acid corrosion method, and then introduce the substrate into an ultrahigh-vacuum film-preparation system, whose specimen stage possesses heating and cooling functions;
2) raise the temperature to 750° C.˜950° C. under ultrahigh vacuum to remove a remaining silicon oxide layer, and obtain the clean surface of Si substrate;
3) cool the above-mentioned Si substrate to 100° C.˜−150° C., deposit a metal monocrystal film of 1˜10 nm of magnesium, calcium, strontium or cadmium, and then oxidize the metal film with oxygen gas or an active oxygen source, thus obtaining a halite-phase metal-oxide monocrystal film;
4) deposit the ZnO film on the above-mentioned metal-oxide layer by means of the publicly-known two-step growth method, that is, deposit a ZnO buffer layer of 5˜50 nm at low temperature of −150° C.˜350° C.; and
5) deposit a ZnO epitaxial layer of 300˜1000 nm at 400° C.˜700° C., thus obtaining the high-quality ZnO film.

2. The method of manufacturing the high-quality ZnO monocrystal film on the Si (111) substrate according to claim 1, wherein the ultrahigh vacuum film-preparation system is a molecular beam epitaxy system.

3. The method of manufacturing the high-quality ZnO monocrystal film on the Si (111) substrate according to claim 2, wherein a halite-phase magnesium-oxide monocrystal film is prepared in Step 3) by cooling the Si substrate to 30° C.˜−30° C., depositing the metal Mg monocrystal layer of 1˜10 nm, and then oxidizing the metal Mg film with the active oxygen source for 10˜30 minutes; and then in Step 4) the ZnO buffer layer of 5˜50 nm is deposited on the magnesium oxide layer at low temperature of −30° C.˜350° C.

4. The method of manufacturing the high-quality ZnO monocrystal film on the Si (111) substrate according to claim 2, wherein a halite-phase calcium-oxide monocrystal film is prepared in Step 3) by cooling the Si substrate to −10° C.˜−100° C., depositing the metal Ca monocrystal layer of 1˜5 nm, and then oxidizing the metal Ca film with the active oxygen source for 10˜30 minutes; and then in Step 4) the ZnO buffer layer of 5˜50 nm is deposited on the calcium oxide layer at low temperature of −100° C.˜350° C.

5. The method of manufacturing the high-quality ZnO monocrystal film on the Si (111) substrate according to claim 2, wherein a halite-phase strontium-oxide monocrystal film is prepared in Step 3) by cooling the Si substrate to −50° C.˜−150° C., depositing the metal Sr monocrystal layer of 1˜5 nm, and then oxidizing the metal Sr film for 10˜30 minutes by introducing oxygen gas or active oxygen; and then in Step 4) the ZnO buffer layer of 5˜50 nm is deposited on the strontium oxide layer at low temperature of −150° C.˜350° C.

6. The method of manufacturing the high-quality ZnO monocrystal film on the Si (111) substrate according to claim 2, wherein a halite-phase cadmium-oxide monocrystal film is prepared in Step 3) by cooling the Si substrate to 100° C.˜−20° C., depositing the metal Cd monocrystal layer of 2˜10 nm, and then oxidizing the metal Cd film with the active oxygen source for 10˜30 minutes; and then in Step 4) the 5˜50 nm ZnO buffer layer is deposited on the cadmium oxide layer at low temperature of −20° C.˜350° C.
